(19) United States
(12) Patent Application Publication
(10) Pub. No.: US 2019/0089150 A1
(43) Pub. Date: Mar. 21, 2019

(54) DISTRIBUTED ELECTROSTATIC DISCHARGE PROTECTION FOR CHIP-TO-CHIP COMMUNICATIONS INTERFACE

(71) Applicant: KANDOU LABS, S.A., Lausanne (CH)

(72) Inventors: Kiarash Gharibdoust, Lonay (CH); Armin Tajalli, Chavannes pres Renens (CH); Christoph Walter, Lausanne (CH)

(21) Appl. No.: 15/709,318

(22) Filed: Sep. 19, 2017

(51) Int. Cl. H02H 9/04; H01F 29/02

(52) U.S. Cl. CPC H02H 9/046; H01F 29/02

(57) ABSTRACT

Directing an electrostatic discharge received via a conductive pad through a multi-tap inductor having a signal path connecting the conductive pad to a signal processing circuit, the multi-tap inductor having a sequence of taps located at positions along a signal path from the conductive pad to the signal processing circuit, distributing the electrostatic discharge as a plurality of currents through the sequence of taps, wherein magnitudes of the plurality of currents are controlled by current-distribution resistors connected to respective taps of the sequence of taps, and dissipating the plurality of currents using a plurality of electrostatic discharge (ESD) circuits connected to the plurality of current-distribution resistors.

### REFERENCES

The following prior applications are herein incorporated by reference in their entirety for all purposes:

U.S. Pat. 9,100,232, issued Aug. 4, 2015, naming Amin Shokrollahi, Ali Hormati, and Roger Ulrich, entitled “Method and Apparatus for Low Power Chip-to-Chip Communications with Constrained ISI Ratio”, hereinafter identified as [Shokrollahi I].

The following additional references to prior art have been cited in this application:

C. Ito, K. Banerjee and R. W. Dutton, “Analysis and design of distributed ESD protection circuits for high-speed mixed-signal and RF ICs,” in IEEE Transactions on Electron Devices, vol. 49, no. 8, pp. 1444-1454, August 2002, hereinafter identified as [Ito].

D. Linten et al., “T-diodes—a novel plug-and-play wideband RF circuit ESD protection methodology,” 2007 29th Electrical Overstress/Electrostatic Discharge Symposium (EOS/ESD), Anaheim, Calif., 2007, pp. 4A.1-1-4A.1-8, hereinafter identified as [Linten].

R. Navid et al., “A 40 Gb/s Serial Link Transceiver in 28 nm CMOS Technology,” in IEEE Journal of Solid-State Circuits, vol. 50, no. 4, pp. 814-827, April 2015, hereinafter identified as [Navid].

### FIELD OF THE INVENTION

The present embodiments relate to communications systems circuits generally, and more particularly to the protection of external integrated circuit signal connections from the effects of Electrostatic discharge (ESD).

### BRIEF DESCRIPTION

It has long been understood that integrated circuit elements may easily be damaged or destroyed by high voltage energy discharges into external connections, such as during manual handling or machine insertion during the manufacturing process. Well-known electrostatic discharge models such as the human body model (HBM), charged-device mode (CDM), and machine model (MM) provide representative examples of the voltages, peak duration, and discharge energy associated with such fault events.

Known art Electrostatic Discharge (ESD) protection circuits rely on series resistors or inductors to limit fault current, and clamp diodes to limit fault voltage to introduce significant frequency-dependent signal attenuation. Unfortunately, these same elements significantly degrade the frequency response of the non-fault signal channel, impacting high performance communications.

Embodiments are described herein to mitigate these detrimental characteristics by partitioning the current limiting inductance into multiple segments and arranging voltage clamping components over the multiple segments to evenly distribute fault currents over the available ESD protection network.

Methods and systems are described for directing an electrostatic discharge received via a conductive pad through a multi-tap inductor having a signal path connecting the conductive pad to a signal processing circuit, the multi-tap inductor having a sequence of taps located at positions along a signal path from the conductive pad to the signal processing circuit, distributing the electrostatic discharge as a plurality of currents through the sequence of taps, wherein magnitudes of the plurality of currents are controlled by current-distribution resistors connected to respective taps of the sequence of taps, and dissipating the plurality of currents using a plurality of electrostatic discharge (ESD) circuits connected to the plurality of current-distribution resistors.

This Brief Summary is provided to introduce a selection of concepts in a simplified form that are further described below in the Detailed Description. The Brief Summary is not intended to identify key or essential features of the claimed subject matter, nor is it intended to be used as an aid in determining the scope of the claimed subject matter. Other objects and/or advantages of the present embodiments will be apparent to one of ordinary skill in the art upon review of the Detailed Description and the included drawings.

### BRIEF DESCRIPTION OF FIGURES

FIG. 1 is a schematic of one embodiment of a distributed electrostatic discharge protection circuit.

FIG. 2 illustrates a stacked arrangement of the elements shown in FIG. 1.

FIG. 3 shows two physical layout views of an embodiment as in FIG. 1.

FIG. 4 is a block diagram illustrating a method for distributed ESD protection, in accordance with some embodiments.

FIGS. 5A and 5B are S-parameter simulation results for a multi-wire bus, in accordance with some embodiments.

### DETAILED DESCRIPTION

The physical and electrical interface between an integrated circuit device and the outside world represents a demarcation between the controlled world of the circuit designer, and the unconstrained variability of the real world. Although internal circuits may operate at picoamp and millivolt levels, an electrostatic transient caused by static discharge may induce discharge pulses of hundreds of volts into its external connections. Thus, external connections are protected by an Electrostatic Discharge (ESD) protection circuit.

Well-known electrostatic discharge models such as the human body model (HBM), charged-device mode (CDM), and machine model (MM) provide representative examples of the voltages, peak duration, and discharge energy associated with such transient fault events. The energy source in such models typically represents 100's of picofarads of capacitance charged to 400-1000 volts. Known art Electrostatic Discharge (ESD) protection circuits such as described in [Ito], [Linten], [Navid] rely on series resistors or inductors to limit the resulting discharge current and clamp diodes or thyristors to limit fault voltage. Unfortunately, these same elements can also significantly degrade the frequency response of the non-fault signal channel, impacting high performance communications. In particular, the junction and body capacitance of clamp diodes large enough to handle the fault current can resonate with the current-limiting series inductance, with the resulting frequency-dependent termination anomaly significantly impacting communications signal integrity.

Described herein are embodiments for providing a distributed ESD (DESD) circuit to distribute an ESD event as a plurality of currents through multiple taps of an inductor. Furthermore, examples are described that utilize die area under the contact pad (or “bump”) to place the inductor so as to reduce the amount of die area for the DESD circuit. By splitting a singular large ESD diode capacitance into several smaller ESD diode capacitances, the distributed matching-network provides increased bandwidth. In such embodiments, the smaller capacitances of each ESD are nulled-out by corresponding inductances at certain frequencies, which are designed to be inside the frequency band of interest. Such embodiments yield multiple resonance frequencies in the matching network, hence, improving the S-parameter “S11” for the system.

### Vector Signaling Codes

As described in [Shokrollahi I], vector signaling codes enable the efficient communication of data over a communications medium that may be composed of multiple essentially parallel wires. For Orthogonal Differential Vector Signaling (ODVS) codes, up to N-1 bits of binary data may be carried over an N wire channel. Using as an example the Glasswing code of [Shokrollahi I], N-1=five binary bits may be encoded into an N=six symbol codeword, utilizing an alphabet of four distinct values.

The ability of efficiently encoding and decoding the Glasswing code facilitates high speed operation. As one example, [Shokrollahi I] describes one embodiment of the Glasswing code operating at 25 Giga-codewords per second (25 GHz), i.e. a unit interval of 40 picoseconds. At these significant signaling rates, a conventional approach to Electrostatic Discharge (ESD) protection for external integrated circuit connections cannot be used without significantly affecting communications integrity over those connections. Subsequent examples herein will use the Glasswing code and its six-wire bus embodiment as a descriptive example without implying limitation.

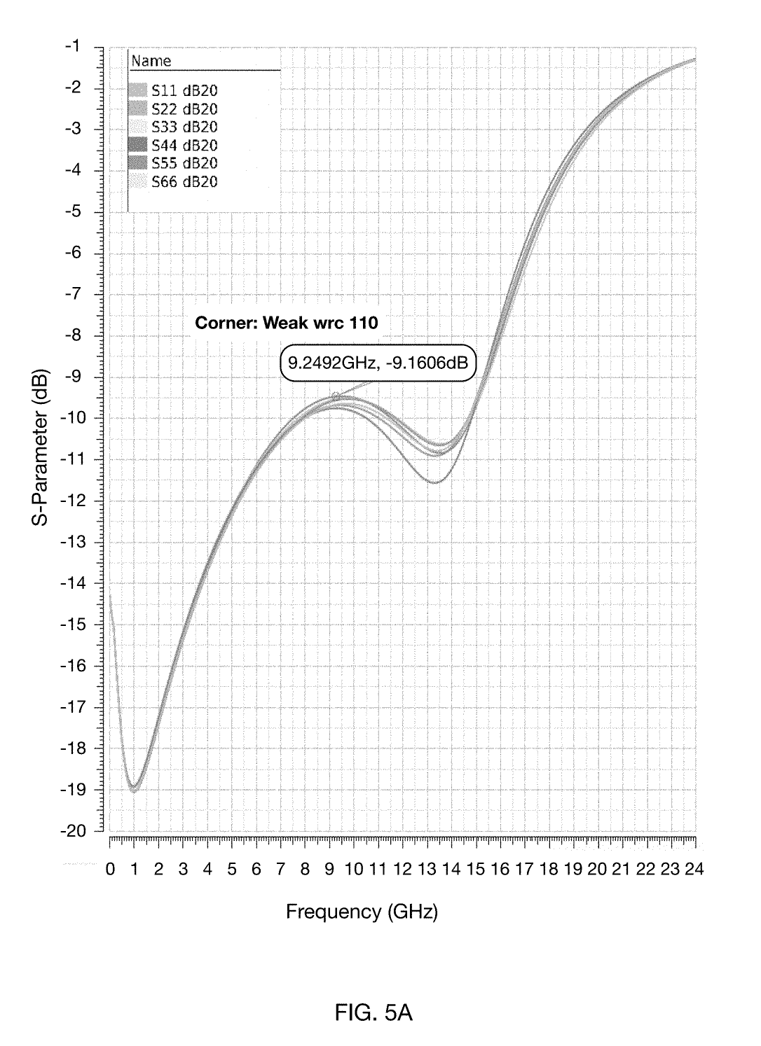

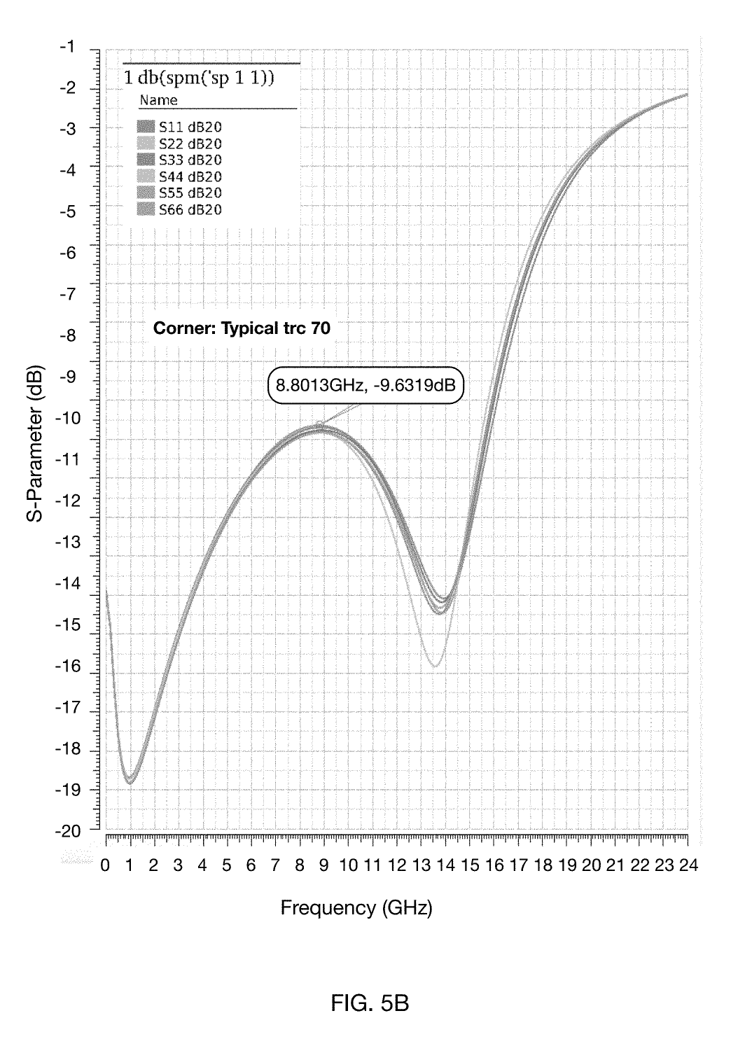

FIGS. 5A and 5B illustrate simulation results for the S-parameter for the Glasswing code mentioned above. As shown, each simulation includes six waveforms, each waveform corresponding to a simulation performed on one of the six wires of the multi-wire bus. Both simulations include resonance frequencies near 12.5 GHz, which corresponds to the Nyquist frequency of the data rate of 25 GHz mentioned above, and nulls near

### Combined Termination and ESD Circuit

To minimize skew and inter-symbol interference, each vector signaling code channel should be terminated identically, ideally into a matching impedance for the transmission medium. The desirability of using a split-T termination inductance (i.e. one having both a series pass element and a parallel or shunt termination element) was indicated by signal integrity analysis, and methods described herein mitigate the effect of the parasitic capacitance of the ESD clamp diodes.

As is well-understood, transient signals such as generated by common ESD models can inject significant peak currents into external integrated circuit connections during the static discharge pulse. Thus, the current-limiting impact of a series inductor or coil may, for some range of pulse waveforms, be represented by both the inductive reactance and the ohmic resistance of the coil material. To avoid ambiguity, the following descriptions will use the term “effective impedance” to describe the resulting fault-pulse-current limitation factor, versus “resistance” for a simply ohmic limitation, with the understanding that in some embodiments (e.g. having slow-rising or long duration fault pulse waveforms) the effective impedance will be derived primarily from the ohmic resistance of the circuit, while in other embodiments (e.g. having fast-rising or short duration fault pulse waveforms) the effective impedance may be increased by the effects of the inductive reluctance of the circuit.

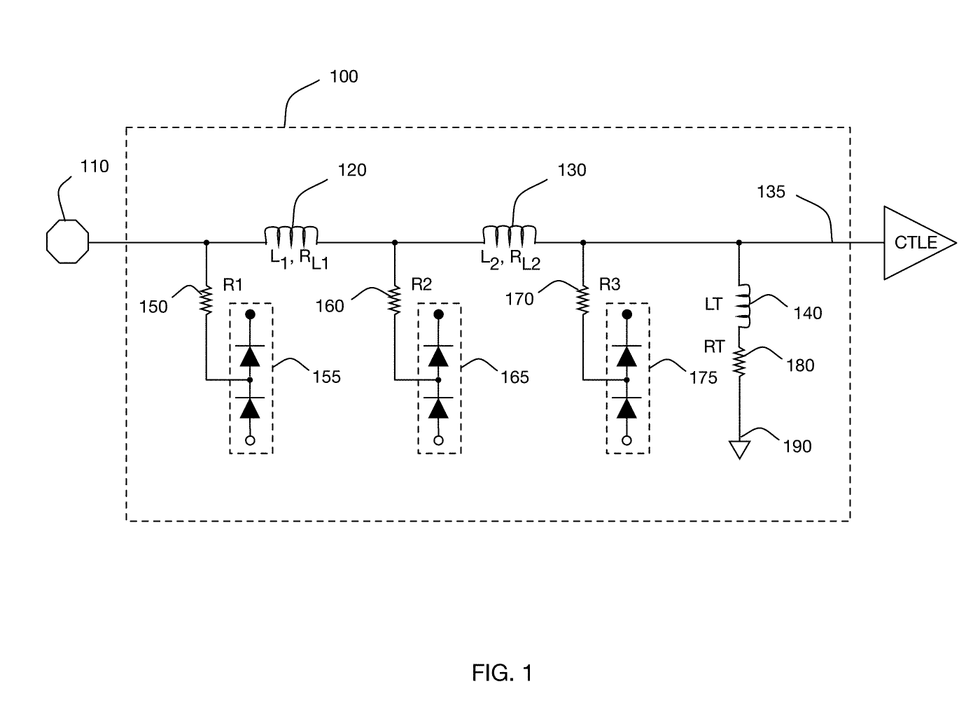

FIG. 1 is a schematic diagram of the matching network 100 for one wire of a network interface embodiment. Bonding pad 110 provides the external connection to the integrated circuit; in some embodiments, this may alternatively be a bump, through-silicon via (TSV), or other equivalent external connection point. The signal output 135 is shown connecting to the first active processing stage of the digital receiver, which is here shown as a Continuous Time Linear Equalizer or CTLE, without implying limitation.

As shown in FIG. 1, the multi-tap inductor (which may be a T-coil inductor) used for transmission line matching has been partitioned into three segments; serial segments 120 and 130, and shunt segment 140. Further shown is the termination resistor 180 for this wire of the network interface. Although termination resistor 180 is shown connected to signal ground at node 190, in some embodiments the terminations for all network wires would instead be star-connected to a common node. In a first embodiment, this common node is provided with a common mode or common bias voltage from a local voltage regulator. In a second embodiment, this common node develops a common mode or common bias voltage due to the balanced nature of the vector signaling code itself, as described in [Shokrollahi I]. In at least one embodiment, capacitive filtering or decoupling is provided between the common node and ground or Vss.

The ESD protection circuits 155, 165, 175 are here represented by pairs of diodes connected to Vdd and Vss, and are distributed along the series signal path from bonding pad 110 to output 135 via a sequence of taps. As shown, each ESD protection circuit is connected to a corresponding tap of the sequence of taps via a corresponding current-distribution resistor. The distribution of a fault current into two or more discharge currents reduces the influence of parasitic capacitance during normal operation, and permits the fault current to be spread across multiple ESD clamping elements during a static discharge event.

The effective impedance of 120 and 130 progressively attenuates the peak current of an ESD event, thus without further correction ESD protection circuit 155 would be under greater ESD stress than 165 or 175. Current-distribution resistors 150, 160, 170 equalize these stresses, permitting the fault current to be distributed evenly across the multiple ESD clamping elements as a plurality of discharge currents.

In a first embodiment, the resistive values of current-distribution resistors 150, 160, 170 progressively decrease, with highest-value current-distribution resistor 150 being closest to input bonding pad or bump 110, middle-value current-distribution resistor 160 separated from 150 by one inductive segment 120, and lowest-value current-distribution resistor separated from 150 by two inductive segments 120 and 130. In a second embodiment, resistive values of 150, 160, and 170 are associated at least in part with the effective impedance of inductive elements 120 and 130. It should be noted that while three segments are shown in FIG. 1, generally two or more segments may be used in such a distributed ESD network, including one shunt segment and at least one serial segment.

In at least one embodiments, values for the current-distribution resistors R1-R3 may be computed as follows:

R₂=R_{L2}+R₃ and (eqn. 1)

R₁=(2*R_{L1})+R₂ (eqn. 2)

In particular, in at least one embodiment where R₃=0, approximately equal fault current distribution may be obtained when:

R₂≅R_{L2}≠0 (eqn. 3)

R₁≅(2*R_{L1})+R_{L2}≠0 (eqn. 4)

Similar computations may be performed to obtain the desired distributed fault current flows for distributed ESD embodiments utilizing fewer or greater numbers of inductive segments and ESD protection circuits.

The above equations give one exemplary relationship to distribute current throughout the various taps, however it should be noted that alternative relationships may be utilized as well. For example, some embodiments may balance the amount of current discharged through each path while alternative embodiments may distribute current unevenly throughout the paths. Similarly, ESD protection devices such as diodes may be of equal size, or may be scaled in size and fault current carrying capacity.

In some embodiments in which current distribution is designed to be uneven (and hence, ESD devices may have different sizes by design), the equations above may be modified as below. Such embodiments that utilize uneven current distribution may be favorable in situations where different sized ESD protection devices are used. Such an example may incorporate larger ESD devices towards the pad with smaller ESD devices towards the output. In such embodiments, there may be more room near the pad, and a larger portion of the electrostatic discharge may be distributed in the larger ESD device. Consider the current-distribution weights for ESD devices 155, 165, and 175 as being ‘1’, ‘a’, and ‘b’, respectively, where ‘a’ and ‘b’ represent the relative current-distribution weights with respect to the current-distribution weight for ESD device 155. Eqns. 1 and 2 above may now be written as:

R₂×α=(R_{L2}+R₃)×b; and (eqn. 5)

R₁=(α+b)×R_{L1}+α×R₂ (eqn. 6)

In the above embodiments, the resistor values may be replaced by effective impedances to reflect frequency dependency. In some embodiments, replacing one or more of current-distribution resistors R1-R3 with inductors may allow for tuning of the resonance frequencies associated with the system. Alternatively, inductors may be included in series with the current-distribution resistors to adjust the resonance frequencies.

In some embodiments, a first ESD device located nearest to the conductive pad has a size between 1.3-2.0× larger than a second ESD device in the DESD circuit. Devices with ratios in this range provide for a greater current to be discharged in the first stage of the protection circuit, while still providing enhanced frequency response for wideband operation. In some embodiments, the second ESD device may be adjacent to the first ESD device, or there may be a third ESD device in between the first and second ESD devices. In some embodiments, the first ESD device is 1.5× larger than the second ESD device. In such an embodiment, the first ESD device may discharge a larger portion of the ESD event as a larger current with respect to the subsequent discharge currents.

Current integrated circuit processes provide for multiple metallization layers suitable for fabrication of inductive coils. One embodiment fabricates inductive segments 120, 130, 140 as a stack of two or more metallization layers, with each layer incorporating one or more turns of coil. A second embodiment extends this stack to include the bonding pad or bump on a top metallization layer, and inductive segments on lower metallization layers beneath the bonding pad or bump. A third embodiment further extends this stacking concept, with current distribution resistors 150, 160, 170 connecting from inductive coil taps to diodes or other ESD clamping element fabricated in the underlying active semiconductor layers of the integrated circuit.

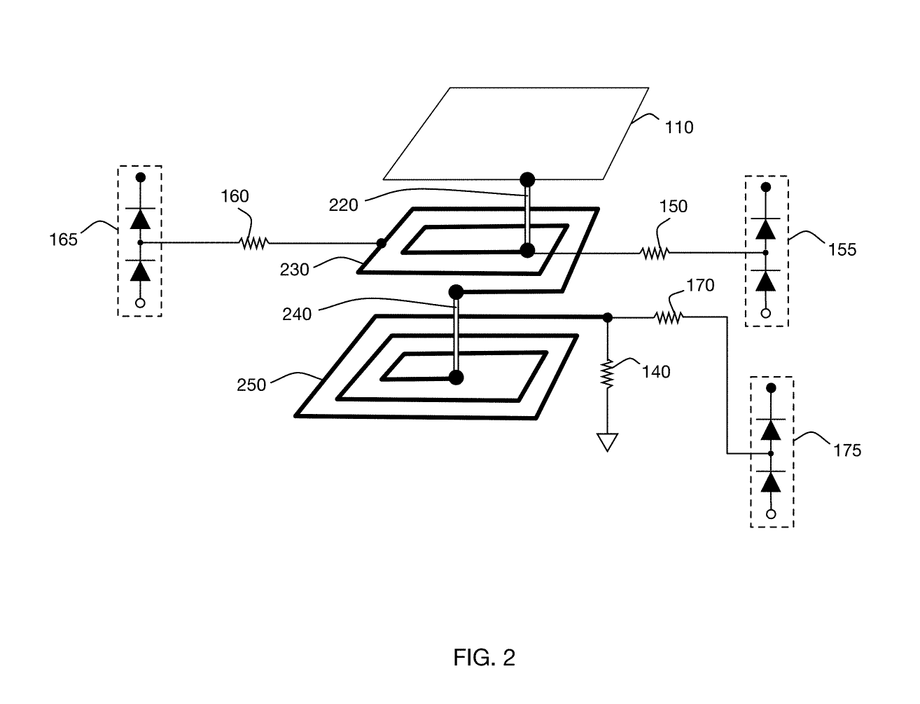

A pictorial illustration of such a stack is shown in FIG. 2. Bump/pad 110 is fabricated from the top metallization layer and is connected by via 220 to tapped series inductor 230 fabricated from a metallization layer beneath the bump pad. Similarly, via 240 and inductor 250 continues the stacked construction on a third metallization layer. Current-distribution resistors 150, 160, 170 connect inductor segments to ESD protection circuits 155, 165, 175. Termination resistor 140 may provide a matched impedance termination of the network wire.

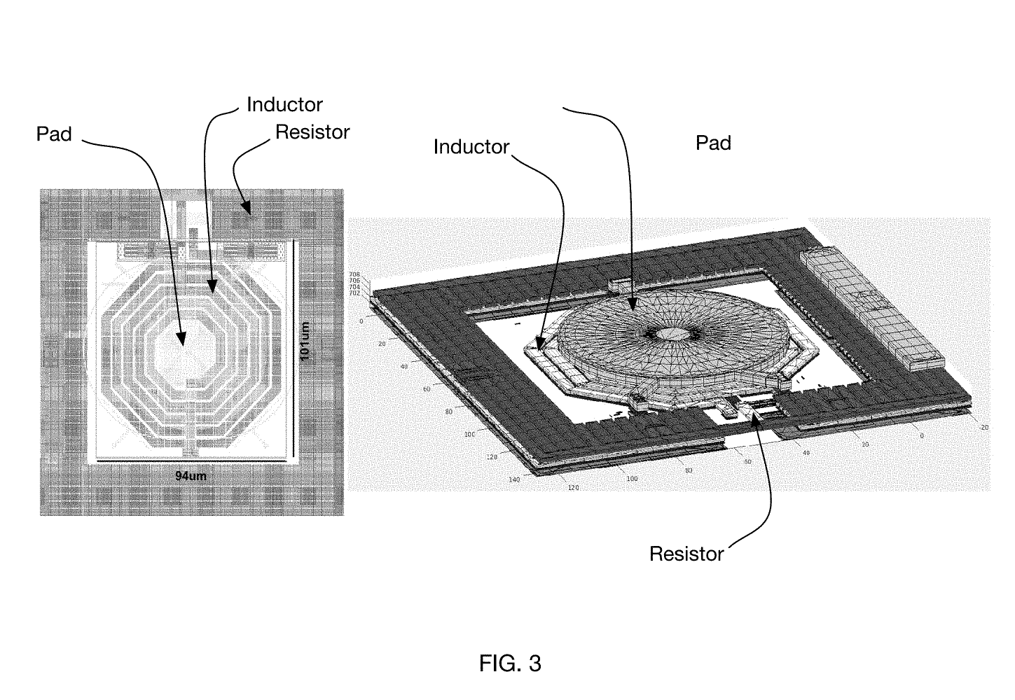

FIG. 3 shows two views of an embodiment utilizing such a stacked layout arrangement, with a multi-tap inductor coil located beneath a bump/pad and inductive taps connecting to fault-current distribution resistors. In the particular fabrication process used in this design, the available resistive material has a very high ohms-per-square value, thus the illustrated low-ohmage resistors may be designed to have wide aspect ratios. The ESD protection diodes are not shown in these views, and are located beneath the illustrated layers. As shown, die area of the chip below the bump/pad is re-utilized by placement of the multi-tap inductor. In such embodiments, an ESD event occurring at the bump/pad is distributed via the multi-tap inductor disposed on one or more circuit layers beneath the bump/pad as a plurality of discharge currents through the plurality of ESD protection diodes. Such an embodiment reduces the overall die area utilized by the combination of the bum/pad and the DESD circuit. As shown in FIG. 2, the multi-tap inductor is disposed on two separate layers with respect to the layer that includes the pad, and is situated beneath the pad. As shown, each layer is connected to at least one other layer using vias.

While the above embodiments distribute the fault current among three protection devices, alternative embodiments may utilize two protection devices, omitting the circuit instance including elements 130, 170, 175 in FIG. 1. Alternatively, further embodiments may similarly utilize more than three protection devices, by replicating multiple circuit instances composed of an inductive segment, a current-distribution resistor, and an ESD protection device.

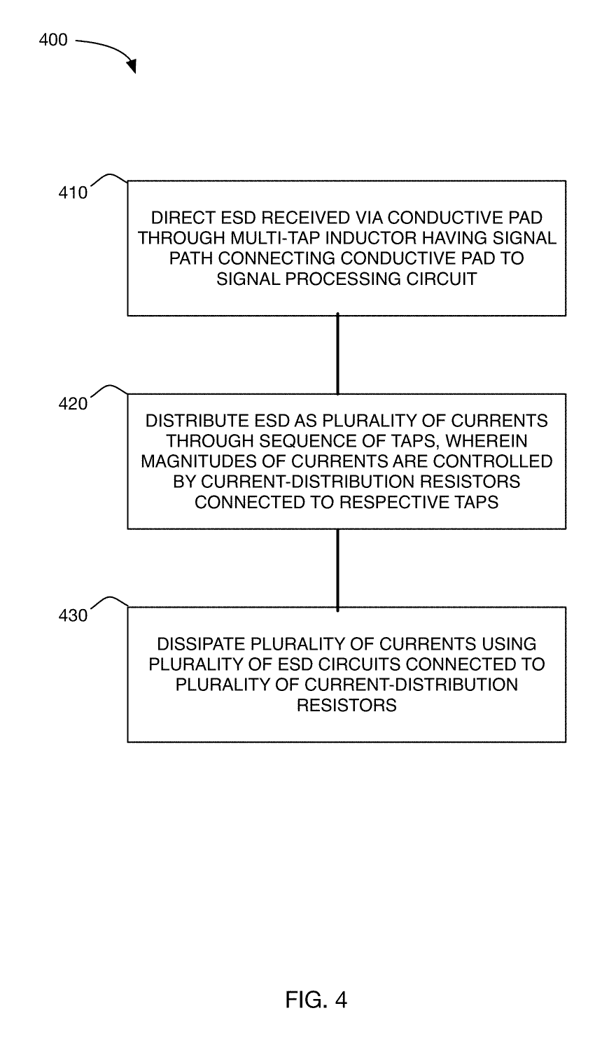

As shown, FIG. 4 illustrates a flowchart of a method 400, in accordance with some embodiments. As shown, method 400 includes directing 410 an electrostatic discharge received via a conductive pad through a multi-tap inductor having a signal path connecting the conductive pad to a signal processing circuit, the multi-tap inductor having a sequence of taps located at positions along a signal path from the conductive pad to the signal processing circuit. At 420, the electrostatic discharge is distributed as a plurality of currents through the sequence of taps, wherein magnitudes of the plurality of currents are controlled by current-distribution resistors connected to respective taps of the sequence of taps. At 430, the currents are dissipated using a plurality of electrostatic discharge (ESD) circuits connected to the plurality of current-distribution resistors.

In some embodiments, each plurality of current-distribution resistor has an impedance value associated with a position of the respective tap. In some embodiments, the impedance value for a first current-distribution resistor is larger than the impedance value for a second current-distribution resistor. In some embodiments, the first current-distribution resistor is connected to a tap in a location closer to the conductive pad.

In some embodiments, each current-distribution resistor of the plurality of current-distribution resistors has an impedance value associated at least in part with the effective impedance of segments of the multi-tap inductor between each tap of the sequence of taps.

In some embodiments, the multi-tap inductor and the conductive pads are on respective metallization layers, the metallization layer of the multi-tap inductor being beneath the metallization layer of the conductive pad. In some embodiments, the multi-tap inductor is a T-coil inductor. In such embodiments, the T-coil inductor may be a multi-layered T-coil inductor.

In some embodiments, distributing the electrostatic discharge as the plurality of currents includes directing the plurality of currents to the one or more ESD protection circuits using vias, as shown in FIG. 2. In some embodiments, each of the plurality of currents have equal magnitudes.

1. An apparatus comprising:
a conductive pad connected to a wire of a multi-wire bus;
a multi-tap inductor connected to the conductive pad and a signal processing circuit, the multi-tap inductor having a sequence of taps located at positions along a signal path from the conductive pad to the signal processing circuit, the multi-tap inductor configured to distribute an electrostatic discharge as a plurality of currents through the sequence of taps;
a plurality of current-distribution resistors, each current-distribution resistor connected to a respective tap of the sequence of taps of the multi-tap inductor, the plurality of current-distribution resistors configured to control magnitudes of the plurality of currents; and
a plurality of electrostatic discharge (ESD) circuits, each ESD circuit connected to a respective current-distribution resistor, the plurality of ESD circuits configured to dissipate the plurality of currents.

2. The apparatus of claim 1, wherein each current-distribution resistor of the plurality of current-distribution resistors has an impedance value associated with a position of the respective tap.

3. The apparatus of claim 2, wherein the impedance value for a first current-distribution resistor is larger than the impedance value for a second current-distribution resistor.

4. The apparatus of claim 3, wherein the first current-distribution resistor is connected to a tap in a location closer to the conductive pad.

5. The apparatus of claim 1, wherein each of the plurality of current-distribution resistors has an impedance value associated at least in part with the effective impedance of segments of the multi-tap inductor between each tap of the sequence of taps.

6. The apparatus of claim 1, wherein the multi-tap inductor and the conductive pads are on respective metallization layers, the metallization layer of the multi-tap inductor being beneath the metallization layer of the conductive pad.

7. The apparatus of claim 1, wherein the multi-tap inductor is a T-coil inductor.

8. The apparatus of claim 7, wherein the T-coil inductor is a multi-layered T-coil inductor.

9. The apparatus of claim 1, wherein one or more ESD protection circuits are connected to the taps of the multi-tap inductor by vias.

10. The apparatus of claim 1, wherein each of the plurality of currents have equal magnitudes.

11. A method comprising:
directing an electrostatic discharge received via a conductive pad through a multi-tap inductor having a signal path connecting the conductive pad to a signal processing circuit, the multi-tap inductor having a sequence of taps located at positions along a signal path from the conductive pad to the signal processing circuit;
distributing the electrostatic discharge as a plurality of currents through the sequence of taps, wherein magnitudes of the plurality of currents are controlled by current-distribution resistors connected to respective taps of the sequence of taps; and
dissipating the plurality of currents using a plurality of electrostatic discharge (ESD) circuits connected to the plurality of current-distribution resistors.

12. The method of claim 11, wherein each current-distribution resistor of the plurality of current-distribution resistors has an impedance value associated with a position of the respective tap.

13. The method of claim 12, wherein the impedance value for a first current-distribution resistor is larger than the impedance value for a second current-distribution resistor.

14. The method of claim 13, wherein the first current-distribution resistor is connected to a tap in a location closer to the conductive pad.

15. The method of claim 11, wherein each current-distribution resistor of the plurality of current-distribution resistors has an impedance value associated at least in part with the effective impedance of segments of the multi-tap inductor between each tap of the sequence of taps.

16. The method of claim 11, wherein the multi-tap inductor and the conductive pads are on respective metallization layers, the metallization layer of the multi-tap inductor being beneath the metallization layer of the conductive pad.

17. The method of claim 11, wherein the multi-tap inductor is a T-coil inductor.

18. The method of claim 17, wherein the T-coil inductor is a multi-layered T-coil inductor.

19. The method of claim 11, wherein distributing the electrostatic discharge as the plurality of currents comprises directing the plurality of currents to the one or more ESD protection circuits using vias.

20. The method of claim 11, wherein each of the plurality of currents have equal magnitudes.
